(19) United States
(12) Patent Application Publication
(10) Pub. No.: US 2019/0099777 A1
(43) Pub. Date: Apr. 4, 2019

(54) COMPRESSIBLE MEDIA APPLICATOR, APPLICATION SYSTEM AND METHODS FOR SAME

(71) Applicant: Intel Corporation, Santa Clara, CA (US)

(72) Inventors: Ken P. Hackenberg, Plano, TX (US); Nachiket R. Raravikar, Saratoga, CA (US); James C. Matayabas, JR., Chandler, AZ (US); Elizabeth Nofen, Phoenix, AZ (US); Seth B. Reynolds, Chandler, AZ (US); Amram Eitan, Scottsdale, AZ (US); Nisha Ananthakrishnan, Chandler, AZ (US)

(21) Appl. No.: 15/720,655

(22) Filed: Sep. 29, 2017

(51) Int. Cl. B05C 5/02; B05C 11/10

(52) U.S. Cl. CPC B05C 5/0237; B05C 5/0208; H01L 21/67023; B05C 11/1042; B05C 11/1026

(57) ABSTRACT

A fluid applicator configured to apply a fluid to at least one substrate feature includes a manifold plate having an inflow orifice and a manifold reservoir. A distributor plate is coupled with the manifold plate. The distributor plate includes a distributor surface extending across the manifold reservoir, and a distributor port array spread across the distributor surface and in communication with the manifold reservoir. A compressible reticulated media is configured for applying the fluid to the at least one substrate feature. The compressible reticulated media includes an input interface coupled along the distributor surface, and a substrate interface having an applicator profile corresponding to a feature profile of the at least one substrate feature. Reticulations extend from the input interface to the substrate interface, and the reticulations are distributed across the substrate interface.

### TECHNICAL FIELD

This document pertains generally, but not by way of limitation, to the controlled application of fluids to work pieces.

### BACKGROUND

Fluids are applied between interfacing surfaces of semiconductors, substrates, chips (e.g., packages including semiconductors and substrates) or the like for treating the surfaces prior to bonding or to facilitate bonding. For instance, flux is applied across the interfacing surfaces of components to remove oxides from materials in preparation for connection to promote bonding and reliable electrical connections. In one example, flux is used with metallic electrical interfaces including solder bumps, solder bump arrays or the like.

In other examples, epoxies or other bonding agents are applied across interfacing surfaces (e.g., of semiconductors, substrates, chips or the like) to bond components together. The epoxies interact with the materials of the interfacing surfaces and bond the respective components together.

Fluids are applied between interfacing surfaces through dip and spray applicators. With dip applicators a component, such as a semiconductor, having an array of solder bumps is grasped and manipulated relative to a reservoir of a fluid (e.g., flux, bonding agent or the like). The manipulator mechanism lowers the component into the reservoir until the interfacing surfaces (e.g., solder bumps or the like) engage the fluid. The component is removed from the reservoir, and is then heated (e.g., to melt or achieve a glass transition temperature) to facilitate the bonding of the component solder bumps with a substrate.

With spray applicators the component is held in a fixture and one or more spray nozzles are passed over the component to apply the fluid (e.g., flux, bonding agent or the like). A manipulator including one or more actuators moves the spray nozzle in a pattern (e.g., an x and y rasterized pattern) over the specified portion of the component until the portion is covered with a film of the fluid. At least one of the components is then optionally heated and engaged with the opposed component for bonding.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a schematic view of one example of a fluid application system including a compressible reticulated media.

FIG. 2 is a cross sectional view of one example of compressible reticulated media.

FIG. 3A is a perspective view of one example of a substrate including at least one substrate feature.

FIG. 3B is a perspective view of another example of a substrate including at least one substrate feature.

FIG. 3C is a perspective view of yet another example of a substrate including at least one substrate feature.

FIG. 4 is a perspective view of one example of a fluid applicator.

FIG. 5A is an exploded view of the fluid applicator shown in FIG. 4.

FIG. 5B is a cross sectional view of the fluid applicator shown in FIG. 4.

FIG. 6A is a top view of one example of a distributor plate.

FIG. 6B is a top view of another example of a distributor plate.

FIG. 6C is a top view of yet another example of a distributor plate.

FIG. 7A is a schematic view of the fluid applicator of FIG. 4 disengaged from a substrate.

FIG. 7B is a schematic view of the fluid applicator of FIG. 4 engaged with the substrate.

FIG. 7C is a schematic view of the fluid applicator of FIG. 4 disengaged from the substrate after deposition of the fluid.

FIG. 8A is a perspective view of one example of a fluid reservoir.

FIG. 8B is a perspective view of one example of a valve operator configured for use with the fluid reservoir of FIG. 8A.

FIG. 9A is a schematic view of another example of a fluid applicator including the fluid reservoir and the valve operator of FIGS. 8A, B disengaged from a substrate.

FIG. 9B is a schematic view of the fluid applicator of FIG. 9A in a dispensing configuration, and having a valve actuator opening the fluid reservoir.

FIG. 10 is a block diagram showing one example of a method for distributing fluid in a fluid applicator.

### DETAILED DESCRIPTION

The present inventors have recognized, among other things, that a problem to be solved can include increasing the speed of fluid application to components, such as semiconductors, substrates, chips (e.g., packages including semiconductors and substrates) or the like, while at the same time limiting the reliable application of the fluid to a specified profile (e.g., a feature profile provided on the component). For instance, dipping of a component uses the careful manipulation of a component to ensure engagement of features, such as solder bumps with the fluid in a reservoir. With larger assemblies such as packages, trays or the like it is difficult to dip the assembly and apply fluid to the specified feature profile while also isolating other components of the assembly (in keep out zones or KOZ) from the fluid. Instead, a smaller opposed component without adjacent components, such as a chip or semiconductor, is dipped. The chip or semiconductor is then heated and bonded with the assembly. After bonding, the manipulator cools for a specified time prior to coupling with another component to prevent premature heating of the interfacing surfaces (solder bumps). The manipulation of components, dipping, and cooling of manipulators are each time intensive. Further, nearby features (e.g., other chips, semiconductors or the like in KOZ) on larger assemblies frustrate dipping of the assembly because of potential infiltration of KOZ.

Spray application of fluids in some examples avoids KOZ outside of a zone designated for fluid application (e.g., a feature profile). However, spray application uses one or more nozzles that are moved over the zone in a specified pattern to apply the fluid to the feature profile. The actuation of the nozzles in one or more passes is time intensive. Further, the spray pattern is relatively dense at its center and diffuse at the edges. In one example, the feature profile is covered with a film of fluid that is dense at the center of the feature profile and irregular at the perimeter to avoid infiltration of KOZ. In other examples, the nozzles are passed along the perimeter of the feature profile and the center of the spray pattern passes over the perimeter. In these examples, the diffuse portion of the spray pattern impermissibly infiltrates the KOZ (or a relatively large border is provided that consumes valuable space on a surrounding substrate).

The present subject matter can help provide a solution to this problem, such as by providing a fluid applicator including a compressible reticulated media. The compressible reticulated media includes a substrate interface having an applicator profile that corresponds with a feature profile of a substrate (e.g., a portion of a chip, semiconductor, package, JEDEC tray or the like), such as solder bumps, a solder array, contacts or the like. Reticulations extend through the compressible reticulated media and are distributed across the applicator profile. Engagement and compression of the compressible reticulated media (e.g., a dispensing configuration) across the feature of the substrate applies fluid from the compressible reticulated media to the feature according to the shape and size of the applicator profile corresponding to the feature profile. The example fluid applicators and fluid application systems described herein are configured to rapidly apply fluids (e.g., flux, epoxy, bonding agents, thermal interface material (TIM), cleaning fluids or the like) with enhanced uniformity, precision and accuracy across a specified feature profile. Further, the fluid applicators and fluid application systems apply fluids in a single operation (e.g., depression in a Z direction) in contrast to multiple passes of a spray nozzle. Time intensive manipulation of components, heating and cooling of manipulators with dipping, as well as irregular and time intensive spraying are thereby minimized.

Further, disengagement and expansion of the compressible reticulated media relative to the substrate allows the reticulations to draw in additional fluid for the next application. In some examples, the reticulations are sized (e.g., have an average or median specified diameter) configured to draw in and retain a specified quantity of fluid for the next application. Additionally, the expansion of the media wicks up excess fluid applied across the substrate according to the surface energy (a function of reticulation size, elasticity of the media and the like). Accordingly, excess application of fluid to the substrate is prevented.

This overview is intended to provide an overview of subject matter of the present patent application. It is not intended to provide an exclusive or exhaustive explanation of the disclosure. The detailed description is included to provide further information about the present patent application.

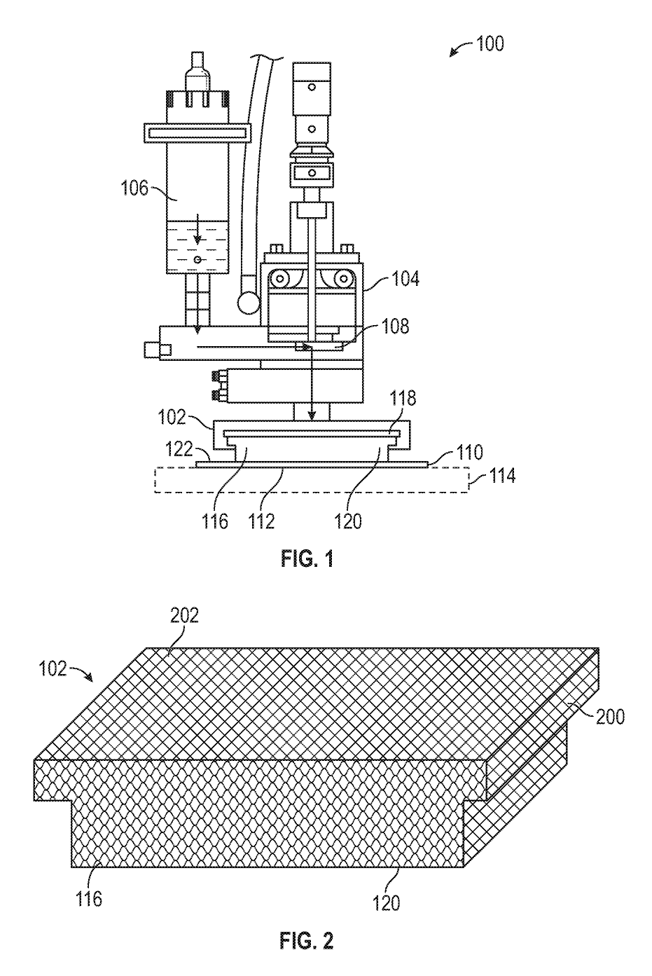

FIG. 1 shows one example of a fluid application system 100. As shown, the fluid application system 100 includes an applicator housing 104 and a fluid applicator 102 coupled with the applicator housing 104. As will be described herein, the fluid applicator 102 includes compressible reticulated media 116 having reticulations such as one or more of pores, passages, lumens or the like extending there through to facilitate the application of fluid to a substrate, for instance, a substrate feature including one or more of solder dots, cylindrical contacts or the like provided on the substrate such as the substrate 110 shown in FIG. 1.

Referring again to FIG. 1, the applicator housing 104 is shown coupled with the fluid applicator 102. The applicator housing 104 includes a fluid reservoir 106 including a fluid therein for dispensing through the fluid applicator 102. Fluids retained within the fluid reservoir 106 include, but are not limited to, flux liquids (liquids configured to remove oxides from materials in preparation for bonding), epoxies, other bonding agents, processing agents, cleaning solutions or the like. The fluid housed in the fluid reservoir 106 is, in one example, one or more fluids used in processing or assembly of one or more components associated with semiconductors, chips or the like. For instance, the fluids include one or more of flux, epoxy, bonding agents, thermal interface material (TIM), cleaning solutions or the like.

The applicator housing 104 further includes a valve assembly 108 or other features configured to constrain and meter the flow of the fluid from the fluid reservoir 106 to the compressible reticulated media 116. As will be described herein, in one example, the valve assembly 108 is a mechanically operated valve assembly. For instance, the valve assembly 108 includes an actuator configured to engage with one or more of the substrate or substrate fixture 114 (shown in FIG. 1) to open the valve assembly 108 with compression of the compressible reticulated media 116 and thereby allow the flow of fluid from the fluid reservoir 106 into the reticulations of the compressible reticulated media 116.

In another example, the valve assembly 108 includes one or more electronic or electrical operators configured to open and close the valve assembly 108 in a selective manner to meter the fluid into the compressible reticulated media 116. In one example, the valve assembly 108 is operated in a similar electrical manner to the mechanical operation of the mechanical valve assembly previously described herein. For instance, as the compressible reticulated media 116 is compressed along the substrate feature 112 of the substrate 110, the valve assembly 108 is electronically opened to facilitate the passage of fluid from the fluid reservoir 106 toward the compressible reticulated media 116. As the fluid application system 100 is withdrawn from the substrate 110, the compressible reticulated media 116 expands and the reticulations are infiltrated by fluid passing through the valve assembly 108. Once the compressible reticulated media 116 is filled with the fluid (e.g., a flux, bonding agent or the like), the valve assembly 108 is configured to close. In the example including an electrically operated valve assembly 108, the valve assembly 108 closes the passage from the fluid reservoir 106 to the compressible reticulated media 116. In the mechanically operated valve assembly 108 previously described herein, the retraction of the fluid application system 100 from the substrate (or conversely the movement of the substrate away from the fluid application system 100 disengages the substrate 110 from the mechanical valve actuator and allows the valve assembly 108 to close.

Optionally, the valve assembly 108 is operated electronically (e.g., with a solenoid) to meter flow of the fluid to the compressible reticulated media 116 in one or more control schemes. For instance, the valve assembly 108 is maintained in a consistently on configuration (e.g., in a consistently operational manufacturing line). In another example, the valve assembly 108 is cycled at one or more specified frequencies (off and on) according to the application work load of the system 100. In other examples, the valve assembly 108 is cycled at one or more specified frequencies based on the liquid applied by the system 100. For example, viscous fluids use a higher frequency (of the on position) while less viscous fluid use a lower frequency.

As further shown in FIG. 1, the compressible reticulated media 116 is coupled with the applicator housing 104. In one example, one or more plates are used to couple the compressible reticulated media 116 in an aligned fashion, for instance, relative to one or more substrate features 112 provided on the substrate 110. As further shown in FIG. 1, the compressible reticulated media 116 includes an input interface 118 positioned proximate to the valve assembly 108. The reticulations of the compressible reticulated media 116 extend from the input interface 118 toward the substrate interface 120 opposed to the input interface 118. In one example, the reticulations of the compressible reticulated media 116 are spread across the substrate interface 120, for instance, along an applicator profile 122 of the substrate interface 120. As will be described herein, in one example, the applicator profile 122 (a size or shape of the fluidly active portion of the compressible reticulated media 116) substantially matches the corresponding feature profile of the substrate feature 112. The compressible reticulated media 116 including the reticulations extending along the applicator profile 122 facilitates the precise delivery of a specified amount of the fluid from the fluid reservoir 106 to the substrate feature 112. Further, because the applicator profile 122 of the substrate interface 120 is configured to correspond with the feature profile of the substrate feature 112 the compressible reticulated media accurately and precisely applies the fluid across the feature profile of the substrate feature 112 and thereby avoids the application of the fluid, for instance, to one or more nearby or proximate features of the substrate 110 (e.g., keep out zones including KOZ or the like).

Referring again to FIG. 1, one example of a substrate fixture 114 is provided in broken lines. In one example, the substrate fixture 114 includes one or more of a table, jig, clamp or the like configured to orientate and hold the substrate 110 including the substrate feature 112 relative to the fluid applicator 102. In one example, the substrate fixture 114 is used to hold the substrate 110 and accordingly align the substrate feature 112 to the fluid applicator 102. Accordingly, the substrate fixture 114 optionally aligns the applicator profile of the compressible reticulated media 116 with the feature profile of the substrate feature 112. In another example, the substrate fixture 114 maintains the substrate 110 at a static location while one or more manipulators, for instance, x and y manipulators move the fluid application system 100 in a relative manner while instruments such as machine vision or fiducial markers are used to control the translation of the fluid application system 100 and align the fluid applicator 102, such as the applicator profile 122 of the substrate interface 120 with the feature profile of the substrate feature 112.

Referring now to FIG. 2, a schematic view of one example of a fluid applicator 102 is shown. As previously described, the fluid applicator 102 includes the compressible reticulated media 116. The compressible reticulated media is constructed with, but not limited to, compressible foam, sponges or the like, elastomeric reticulated substrates, porous substrates or the like. For instance, the media has a plurality of reticulations 202 including, but not limited to, pores, cells, lumens, passage or the like. The reticulations 202 are selectively filled and then emptied through compression of the compressible reticulated media 116 to apply fluid retained in the reticulations 202 to a substrate, for instance, aligned with the substrate interface 120. In one example, the compressible reticulated media 116 is engaged with the substrate feature of the substrate such as the substrate 110 shown in FIG. 1. The substrate interface 120 including, for example, the applicator profile 122 previously described herein is aligned with and accordingly corresponds with a feature profile of the substrate feature 112 of the substrate 110. Optionally, the reticulations 202 extend from the input interface 118 to the substrate 120. In one example, a coating, sealant or the like is applied around the perimeter of the compressible reticulated media 116, for instance, along the side walls and other zones outside of the specified applicator profile 122 between the input and substrate interfaces 118, 120.

As further shown in FIG. 2, the compressible reticulated media 116 optionally includes a retention flange 200 extending from the remainder of the compressible reticulated media 116. As described herein, in at least one example, the compressible reticulated media 116 is retained by the retention flange 200 with one or more features of the applicator housing. For instance, one or more of a retention frame, manifold plate or the like sandwich the retention flange 200 therein and accordingly hold the compressible reticulated media 116 in place relative to the applicator housing (e.g., the applicator housing 104 shown in FIG. 1). In another example, the input interface 118 is bonded with a portion of the applicator housing such as the applicator housing 104. For instance, the input interface 118 is provided with an adhesive or other bonding feature configured to bond the input interface 118 in surface-to-surface contact with corresponding features of the applicator housing 104. One or more openings remain open to the input interface 118 to facilitate the transmission of fluid to the input interface 118 for distribution through the reticulations 202 of the substrate interface 120.

As shown in FIG. 2, the compressible reticulated media 116 extends between its input interface 118 and the substrate interface 120. Accordingly, with engagement of the compressible reticulated media 116 with one or more substrate features such as the substrate feature 112 shown in FIG. 1, the compressible reticulated media 116 is compressed. The reticulations 202 are similarly compressed and fluids such as flux, epoxy, bonding agents, thermal interface material, cleaning fluids or the like within the reticulations 202 are dispensed through the substrate interface 120 to the engaged substrate feature 112. The fluid is applied according to the applicator profile and where the applicator profile corresponds with the feature profile. Accordingly the fluid is uniformly and accurately applied within the boundary of the feature profile of the substrate feature 112 (shown in FIG. 1).

Referring again to FIG. 2, the compressible reticulated media 116 is, in one example, one or more of an elastomeric sponge, foam or the like. For instance, the compressible reticulated media 116 includes, but is not limited to, a polyurethane foam, a silicone foam or the like. The compressible reticulated media 116 is, in one example, not reactive with the fluid conveyed through the reticulations 202 to the substrate. Instead, the (chemically neutral) compressible reticulated media 116 uses capillary forces and surface energy along the reticulations 202 to retain fluid therein on an as-needed basis prior to delivery to one or more substrate features such as the substrate features previously described herein. The reticulations 202 extending through the compressible reticulated media 116 in various examples have a diameter of between 50 and 250 microns. In other examples, the reticulations 202 of the compressible reticulated media 116 have diameters based on the viscosity of the fluid conveyed through the compressible reticulated media 116. For instance, the reticulations 202 of the compressible reticulated media 116 used with viscous fluids are larger compared with the reticulations 202 used with a less viscous fluids.

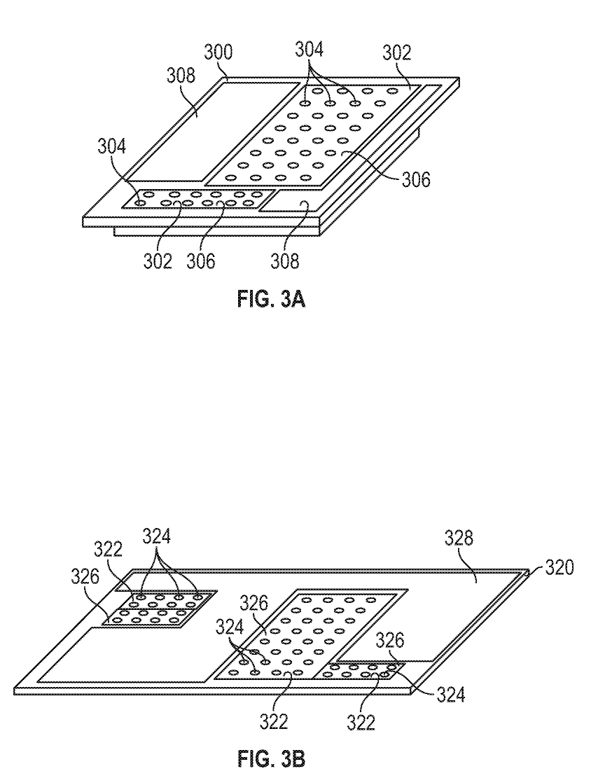

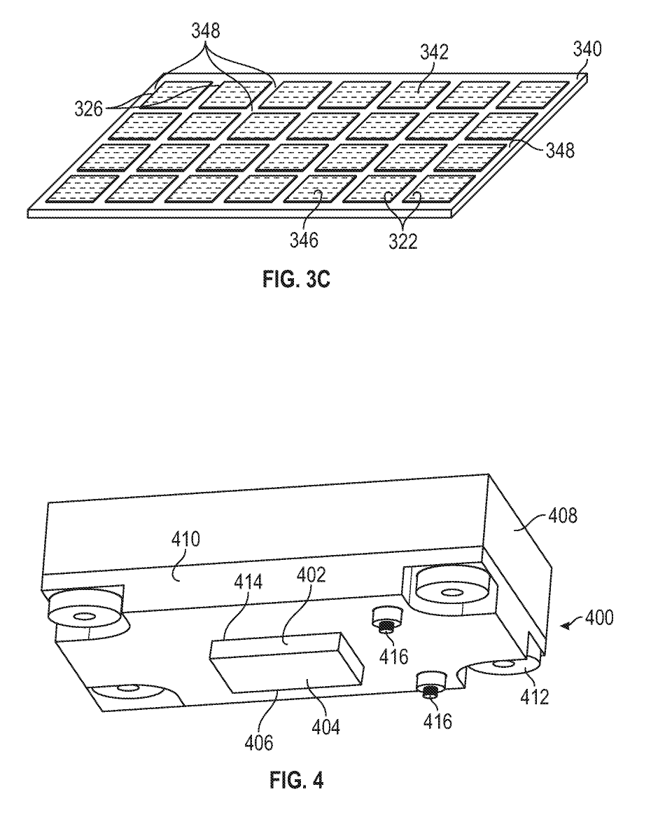

FIGS. 3A, 3B and 3C show various examples of substrates including one or more features configured for reception or application of a fluid. As previously described, the fluid applied includes one or more of flux, epoxy or other bonding agents, processing agents such as thermal interface material, cleaning solutions or the like. Referring first to FIG. 3A, the substrate 300 is shown with a plurality of substrate features 302. In one example, the substrate 300 includes a single substrate feature 302 or one or more component substrate features 302 forming an overall substrate feature. As shown, the substrate features 302, in this example, includes a plurality of component features thereon including, but not limited to, contacts 304. The contacts 304 include one or more of solder dots, posts, pins, pads or the like. As shown in FIG. 3A, the contacts 304 are arranged along the substrate feature 302 while the remainder of the substrate 300, for instance, corresponding to keep out zones 308 (KOZ), are shown with regions (shown with solid lines) proximate to each of the substrate features 302.

Each of the substrate features 302 of the substrate 300 have a corresponding feature profile 306. In the example shown, the substrate features 302 have rectangular or square feature profiles 306. In other examples, the feature profiles 206 have one or more different shapes including L-shapes, rectangular shapes, square shapes, polygonal shapes or the like of one or more sizes each including, for instance, an array of contacts 304. As described herein, the fluid applicator 102 (one example is shown in FIG. 2) includes a compressible reticulated media 116 having a substrate interface 120. The substrate interface 120 includes an applicator profile 122 having a corresponding shape or size to the one or more feature profiles 306 of the substrate 300. Accordingly, with alignment of the substrate 300 with the one or more fluid applicators (again shown in FIG. 2 as applicator 102) application of fluid to the contacts 304 within the feature profile 306 is readily accomplished with a single depression of the fluid applicator onto the feature profiles 306 while the remainder of the substrate 300 is isolated from the fluid (e.g., substantially isolated or entirely isolated).

As further shown in FIG. 3A, the substrate 300 includes one or more keep out zones 308 (KOZ). In various examples, the keep out zones 308 include, but are not limited to, regions of the substrate 300 having sensitive components, components having elevations that otherwise frustrate fluid application through dipping, require time intensive application of fluids through spraying or are in close proximity to the substrate features 302. The components or regions found in the keep out zones 308 are, in some examples, sensitive to fluids applied to the feature profiles 306. The fluid applicator 102, as well as the other applicator examples described herein, include an applicator profile corresponding to the profiles of each of the substrate features 302. Accordingly, the applied fluid is localized to the substrate features 302, for instance, the two feature profiles 306 shown in FIG. 3A of each of the substrate features 302 according to the corresponding applicator profile 122 (or profiles if a plurality of component applicators) of the fluid applicator 102.

FIG. 3B shows another example of a substrate 320. In a similar manner to the substrate 300 previously shown and described in FIG. 3A, the substrate 320 includes one or more substrate features 322 each having, for instance, contacts 324 such as arrays of contacts, pins, pads or the like along each of the substrate features 322. Each of the substrate features 322 further includes a respective feature profile 326 and, as shown in FIG. 3B, each of the feature profiles 326 varies according to the contacts located therein. In a similar manner to FIG. 3A, one or more keep out zones 328 (KOZ) are also provided on the substrate 320 proximate to one or more of the substrate features 322.

Because of the corresponding applicator profile of the fluid applicator 102 (as well as other examples of fluid applicators described herein) fluid is applied to each of the substrate features 322 according to its respective feature profile 326 while the keep out zones 328 are isolated from the fluid. Further, the fluid applicator 102, including a compressible reticulated media 116 as described herein, applies the fluid in a single step and distributes the fluid across the applicator profile (e.g., the profile 142 shown, for instance, in FIG. 1) corresponding to the feature profile 326. The fluid applied by the fluid applicator 102 is accordingly provided in a consistent and even distribution across the substrate features 302 while the keep out zones 328 are substantially from the fluid. In contrast to other fluid application techniques (e.g., spraying or dipping), the fluid applicator 102, including a compressible reticulated media 116 as shown in FIGS. 1 and 2, readily applies a fluid to ach of the substrate features 322 shown, for instance, in FIGS. 3A and 3B and applies the fluid in a single step while isolating one or more components, for instance within the keep out zone 328 or separated by a narrow keep out zone (e.g., relative to a KOZ for spraying) from contact with the fluid.

FIG. 3C shows another example of the substrate 340. In this example, the substrate 340 includes, but is not limited to, one or more of a tray such as a JEDEC tray, sheet, panel or the like including one or more component substrates thereon. In one example, the substrate 340 is a tray configured to facilitate the batch processing of one or more composite substrates thereon. In one example, the composite substrates are shown by substrate features 342 provided in FIG. 3C. As shown, the substrate features 342 are arranged in the substrate 340 in a pattern, for instance, in a group pattern. Although each of the substrate features 342 is shown as having a consistent surface, in one example, the substrate features 342 like the previous example shown in FIGS. 3A and 3B include component features thereon each having, for instance, one or more contactor ways in one or more shapes, locations or the like provided on the substrate features 342. In such an example, the substrate features 342 have their own component keep out zones such as the keep out zones 308, 328 shown in FIGS. 3A and 3B. Referring again to FIG. 3C, additional keep out zones 348 are provided between each of the substrate features 342. The keep out zones 348 shown in FIG. 3C correspond to spaces between each of the substrate features 342, for instance, gaps between each of the substrate features 342 provided on the substrate 340 where the substrate 340 is a tray, sheet or the like configured to hold a plurality of substrate features 342 thereon for batch processing.

As further shown in FIG. 3C, each of the substrate features 342 (e.g., component substrates, for instance, corresponding to one or more of the substrates shown in FIG. 3A, 3B) includes respective feature profiles 346. In the example shown in FIG. 3C, the feature profiles 346 are consistent across each of the substrate features 342. However, in other examples, the feature profiles 346 are provided with a higher resolution, for instance, corresponding to one or more component features such as the features 302, 322 shown in FIGS. 3A and 3B. In one example, fluid is applied by one or more fluid applicators 102, such as an array of fluid applicators provided in a single or composite applicator housing, such as the applicator housing 104 shown in FIG. 1. The fluid applicators 102 are depressed relative to the substrate 340 and engage the respective substrate features 342 aligned with the fluid applicators 102. Accordingly, in a single or limited number steps, the fluid applicators 102 provide fluid to each of the substrate features 342 in a batch process. In one example, the substrate 340 includes, but is not limited to, a tray, JEDEC tray or the like configured for manipulation in a manufacturing or process environment. The substrate 340 is moved along an assembly line, reoriented to another station, and a second substrate 340 including corresponding substrate features 342 in identical or near identical positions to the first substrate 340 is moved into place and processed by the fluid applicators 402.

In another embodiment the substrate 340 includes a plurality of varied substrate features 342 (e.g., substrates including one or more components in various positions or profiles). In this example, a composite applicator housing is used, for instance, with a plurality of fluid applicators 102 each having an applicator profile conforming to a corresponding feature profiles 346 of the substrate feature 342 of each of the substrates 340. Stated another way, each of the fluid applicators 102 includes an applicator profile corresponding to the respective feature profile 346. By providing fluid applicators 102 shaped with corresponding profiles to the unique feature profiles 346 of the substrate features 342 batch processing of a plurality of substrate features 342 is conducted even where the substrate features 342 are different from each other. Further, the batch processing is repeatable, for instance with substrates 340 (JEDEC trays) having the substrate features 342 (packages, chips or the like) arranged in corresponding fashion to the preceding substrate.

Optionally, a number of fluid applicators 102 is used, for instance with a composite applicator housing 104, relative to the substrate features 342 of the substrate 340. The composite applicator housing 104 positions the fluid applicators 102 in alignment a subset of the substrate features 342, applies the fluid (e.g., depresses the applicators 102 into features), and reorients the fluid applicators 102 (or the substrate) to repeat application of the fluid to another subset of the substrate features 342. In this example, the repeated spraying or dipping of individual or subsets of substrate features 342 is minimized (e.g., minimized or eliminated) in favor of the repeatable fluid application to the features through the compressible reticulated media of the applicators 102.

FIG. 4 shows another example of a fluid applicator 400. In this example, the fluid applicator 400 includes compressible reticulated media 402 retained within one or more plates, housings or the like. For instance, the fluid applicator 400 shown in FIG. 4 includes a manifold plate 408 and a retention frame 410. The retention frame 410 includes a media port 414. At least a portion of the compressible reticulated media 402 is provided through the media port 414 and projects from the retention frame 410 for engagement and application of fluid to one or more substrates and substrate features. In one example, the compressible reticulated media 402 housed within the retention frame 410 and the manifold plate 408 includes one or more fastening features configured to retain the media within the fluid applicator. One example of a fastening feature includes the retention flange 200 shown in FIG. 2. Optionally, the retention flange 200 is retained (e.g., clamped) between the retention frame 410 and the manifold plate 408 to fix the compressible reticulated media in a specified location, for instance, in the media port 414.

In another example, the compressible reticulated media 402 is coupled along the input interface (118, shown in FIG. 2) with one or more features of the housing of the fluid applicator 400. As will be described herein, in one example, a distributor plate or the like is provided within the manifold plate 408 to distribute fluid across the compressible reticulated media 402 (e.g., across the input interface) to fill reticulations with fluid for application along the substrate interface 404. In another example, the compressible reticulated media 402 is coupled with portions of the fluid applicator 400, for instance with adhesives, clamps or the like. The compressible reticulated media 402 is coupled with a portion of the fluid applicator 400 such as the distributor plate (previously described) with an adhesive. Optionally, the adhesive is used in combination with clamping of the retention flange 200.

Referring again to FIG. 4, the fluid applicator 400 as shown includes an applicator profile 406 having a rectangular shape as an example. In other examples, the applicator profile 406 is uniquely formed to correspond with one or more substrates or substrate features. For instance, one or more of the substrates or substrate features previously described and shown herein includes its own feature profile, and the corresponding applicator profile 406 has a conforming shape to ensure reliable and consistent application of fluid to the feature profile. The reticulations within the compressible reticulated media 402 are configured to fill with fluid for application through the media 402 and, in one example, are spread across the applicator profile 406. For instance, the reticulations are provided from the interior of the applicator profile 406 (e.g., at the center of the applicator profile) to the perimeter of the applicator profile 406.

In another example, the fluid applicator 400 includes one or more decoupling elements 416. The decoupling elements 416 include, but are not limited to, biasing elements configured to bias the substrate such as one or more of the substrates described herein away from the compressible reticulated media 402. The decoupling elements include, in the example shown, a biasing feature (e.g., spring, elastomer or the like) and pins biased toward one or more of the substrate or substrate features. For instance, as the compressible reticulated media 402 is engaged with and compressed against one or more of the substrate or substrate features, fluid adhesion in some examples occurs. The decoupling elements 416 bias the substrate away from the compressible reticulated media 402 and accordingly break the fluid adhesion.

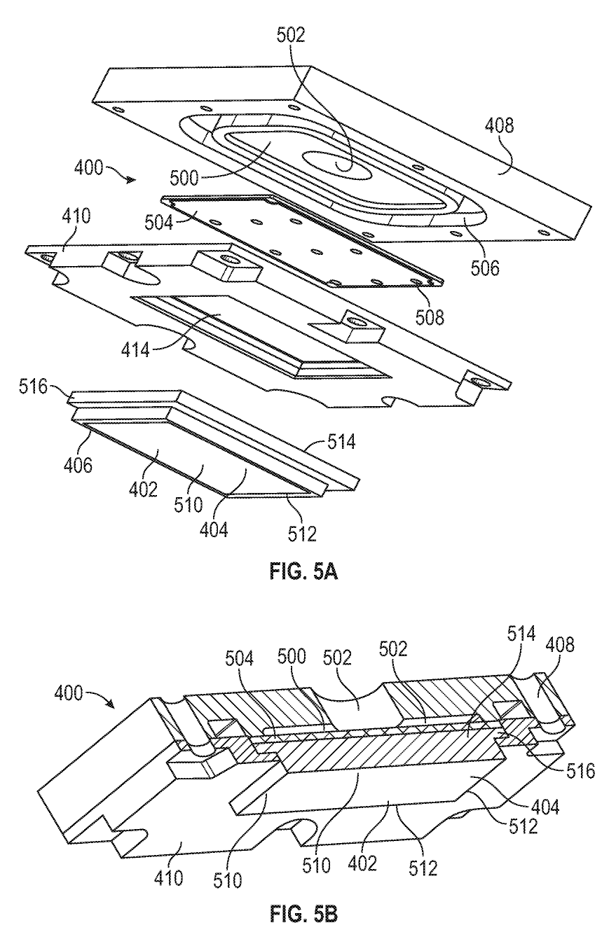

In another example, the fluid applicator 400 is an assembly of multiple components. As previously described, the fluid applicator 400 optionally includes the manifold plate 408, the retention frame 410 and compressible reticulated media 402 as well as other components described herein. As shown in FIG. 5A (herein) the fluid applicator 400 is assembled as a series of layers, plates or the like. Optionally, one or more fasteners 412 shown in FIG. 4 are used to couple the manifold plate 408 and the retention frame 410 with one another and fix the compressible reticulated media 402 therebetween.

FIG. 5A shows an exploded view of the fluid applicator 400 previously shown in FIG. 4. The fluid applicator 400 includes the manifold plate 408 and the retention frame 410. The manifold plate 408 includes a manifold reservoir 500 in communication with an inflow orifice 502. In one example, the inflow orifice 502 is in communication with one or more other features of a fluid application system, such as the system 100 shown in FIG. 1. For instance, the input orifice 502 is, in one example, coupled with or in communication with the valve assembly 108 and the fluid reservoir 106. Accordingly, fluid such as cleaning fluids, flux, bonding agents, epoxies or the like are delivered through the inflow orifice 502 from the system 100. As further shown in FIG. 5A, the manifold reservoir 500 extends laterally away from the inflow orifice 502.

Optionally, a distributor plate 504 (including a deformable membrane, pliable or rigid plates or the like) is configured for reception within and coupling along the manifold reservoir 500. In one example, the distributor plate 504 includes a plurality of distribution ports, such as a distribution port array 508, is arranged in a pattern along the distributor point 504. In one example, distributor plate 504 is configured to distribute fluid from the manifold reservoir over the upper surface of the plate 504, and distribution port array 508 includes one or more perforations configured to deliver the spread fluid to the input interface of the compressible reticulated media 402. Optionally, the distributor plate 504 is sealed against the manifold plate 408 with a gasket, adhesive or the like. For instance, as shown in FIG. 5A, a gasket recess 506 is provided around the perimeter of the manifold reservoir 500. A gasket positioned within the gasket recess 506 engages with one or more of the distributor plate 504 or the retention frame 410 to seal the interior of the manifold plate 408 and thereby prevent the escape of fluid from between the retention frame 410 and the manifold plate 408.

As further shown in FIG. 5A, the retention frame 410 includes a media port 414 sized and shaped for reception of the compressible reticulated media 402. In one example, the compressible reticulated media 402 is positioned within the media port 414 prior coupling with either the manifold plate 408 or the distributor plate 504. For instance the retention flange 200 of the compressible reticulated media 402 is fit along the retention frame 410 including those portions of the retention frame 410 surrounding the media port 414. In another example, a bonding agent, such as an adhesive is applied to the input interface 514 for coupling along the distributor plate 504. The bonding agent affixes the compressible reticulated media 402 in place within the fluid applicator 400. Optionally, the compressible reticulated media includes a retention flange 516 clamped between the retention frame 410 and the manifold plate 408 (or the distributor plate 504). In another example, the compressible reticulated media 402 is coupled with the fluid applicator with both the retention flange 516 and bonding of the media 402 along the distributor plate 504.

As further shown in FIG. 5A, the substrate interface 404 extends from the remainder of the compressible reticulated media 402. The substrate interface 404 includes the applicator profile 406 having a profile corresponding to one or more feature profiles of the substrates described herein (e.g., see substrates such as the substrates 302, 320, 340 and the corresponding features and feature profiles shown in FIGS. 3A-3C). As further shown in FIG. 5A, the applicator profile 406 includes an applicator profile interior and an applicator profile perimeter 510, 512. The applicator profile perimeter 510 extends around the applicator profile interior 510. Optionally, the reticulations of the compressible reticulated media 402 are distributed across the applicator profile 406, for instance, across each of the applicator profile interior 510 and the applicator profile perimeter 512. The compressible reticulated media 402 receives fluid from the distributor plate 504 and the fluid is distributed through the compressible reticulated media 402 (e.g., the reticulations therein) and spread across the entirety of the applicator profile 406 for application to one or more corresponding feature profiles of one or more substrates.

Referring again to FIG. 5A, in one example, the distributor plate 504 is a planar substrate extending across the manifold plate 500. In other examples, the distributor plate 504 includes one or more passages, grooves, channels or the like spreading laterally relative to the inflow orifice 502, for instance, across an upper surface of the distributor plate 504. In one example, the channels, grooves or the like extend in a serpentine fashion (e.g., a single channel extending in a serpentine fashion or multiple channels extending in a serpentine fashion). The distribution port array 508 is optionally in communication with these channels and delivers fluid distributed by the plate 504 to the media 402.

In one example, the distribution port array 508 is provided in a pattern corresponding to the compressible reticulated media 402. For instance, as previously described herein the input interface 514 is bonded with an adhesive to the distributor plate 504. Optionally, the adhesive is supplied along the input interface 514 with the portions of the input interface 514 corresponding to the distribution ports of the array 508 on the distributor plate 504 remaining free of the adhesive or bonding agent to facilitate delivery of fluid from the distributor plate 504 into the reticulations of the compressible reticulated media 402.

FIG. 5B shows a cross sectional view of the assembled fluid applicator 400 previously shown in FIGS. 4 and 5A. The fluid applicator 400 includes the retention flange 516 of the compressible reticulated media 402 coupled between the manifold plate 408 and the retention frame 410. In this example, the distributor plate 504 is provided over the input interface 514 and the compressible reticulated media 402 is accordingly coupled between the manifold plate 408 and the retention frame 410 with the distributor plate 504 interposed therebetween.

As further shown, the inflow orifice 502 is aligned with a portion of the distributor plate 504. Fluid delivered through the inflow orifice 502 is incident to the distributor plate 504 and received within the manifold reservoir 500. The fluid is distributed across the manifold reservoir 500 and the distributor plate 504 and dispensed through the distributor plate 504, for instance, through the distribution port array 508 shown previously in FIG. 5A. The fluid delivered through the distributor plate 504 is delivered to the compressible reticulated media 402. As previously described herein, the reticulations of the compressible reticulated media 402 extend from the input interface 514 to the substrate interface 404. Reticulations are accordingly filled with fluid for application through the fluid applicator 400 prior to engagement of the substrate interface 404 with one or more substrates or substrate features.

In operation, the fluid applicator 400 including the compressible reticulated media 402 filled with fluid is lowered and engaged against one or more substrates, features or the like, for instance, described herein. The engagement of the substrate interface 404 with a substrate compresses the compressible reticulated media 402 and compresses the reticulations therein. Compression of the reticulations dispenses the fluid from the compressible reticulated media 402 to the underlying feature profile 306 of the substrate feature 302 (see FIG. 3A). As previously described, because the applicator profile 406 corresponds with the feature profile 306, fluid from the compressible reticulated media 402 is applied in a localized fashion to the feature profile 306 without spreading, spraying or the like of the fluid to other nearby components, for instance, one or more components within or beyond keep out zones, such as the keep out zone 308 shown in FIG. 3A. Further, because the reticulations are spread throughout the applicator profile 406, for instance, from an applicator profile interior 510 (near to the inflow orifice 502) to the applicator profile perimeter 512 surrounding the applicator profile interior 510 an even distribution of the fluid is achieved across the entire feature profile 306. As previously described herein, the applicator profile 406 is, in other examples, configured with different shapes including, but not limited to, rectangular, square, circular, polygonal shapes or the like corresponding to feature profiles of other substrates features.

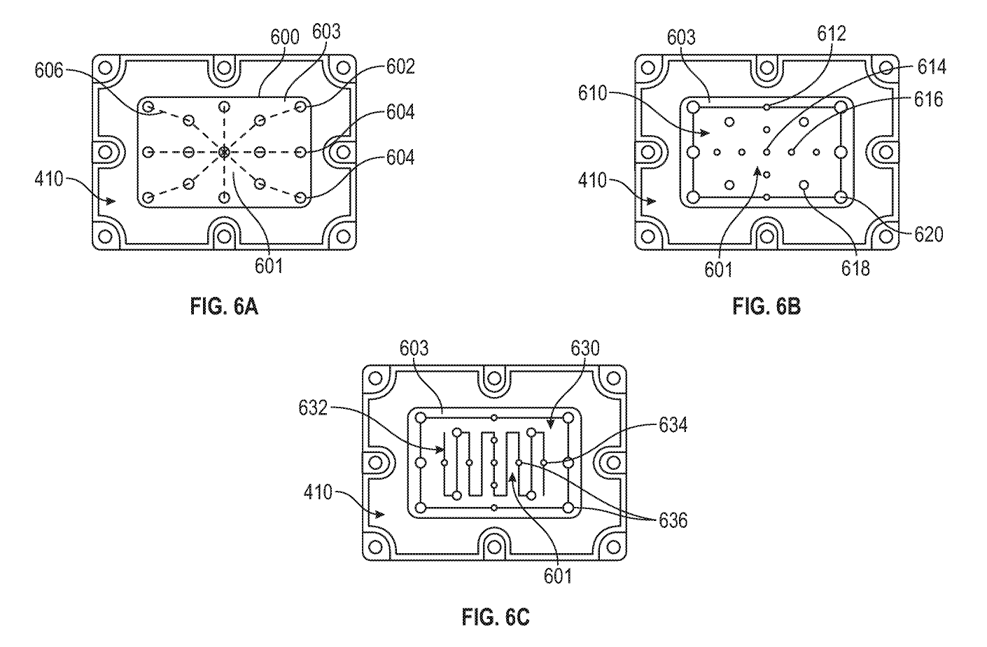

Referring now to FIGS. 6A-C, examples of distributor plates 600, 610, 630 are shown coupled with retention frames 410 (previously shown in FIGS. 4 and 5A). As discussed herein, the distributor plates provide one or more ports (e.g., holes, perforations, channels, grooves or the like) to facilitate the distribution of fluid from an application system (e.g., like the system 100 shown in FIG. 1) to the compressible reticulated media (e.g., media 116, 402 or the like). The distributor plates 600, 610, 630 include variations in ports including differing sizes and profiles of ports and channels configured to enhance distribution of the fluid from the system input, such as the inflow orifice 502, to the input interface 514 of the compressible reticulated media 402 (shown in FIG. 5A).

The distributor plate 600 shown in FIG. 6A includes a plurality of ports 604 forming a port array 602. The ports 604 of the port array 6502 are arranged in a distributed pattern across the plate 600. For instance, the ports 604 are distributed from an interior portion 601 of the plate 600 (e.g., aligned or proximate to the inflow orifice 502 shown in FIG. 5A) to a perimeter portion 603 of the plate 600. In operation, fluid, such as flux, cleaning solutions, TIM or the like is received in the applicator housing from the inflow orifice 502 and is incident along the distributor plate 600. The fluid spreads across the plate 600 to each of the ports 604. The fluid passes through ports 604 to the input interface 514 (see FIG. 5A) of the compressible reticulated media 402 and the reticulations of the media take up the fluid prior to delivery from the substrate interface 404.

In one example, the ports 604 are varied in size, diameter, pattern of the array, and location of the ports according to the fluid conveyed to the media 402 (e.g., larger ports are used with viscous fluids, smaller ports are used with less viscous fluids). In other examples, the application system 100, including a pump, syringe or the like delivers viscous fluids at relatively higher pressures to maintain a desired flow rate of the fluid or saturation of the compressible reticulated media (corresponding optionally to a specified volume applied per application of the media). In still other examples, one or more of the ports 604 or pressure of the system 100 are selected based on the fluid applied by the compressible reticulated media 402, frequency of application of the fluid, specified volume of application of the fluid or the like.

Referring again to FIG. 6A, the distributor plate 600 optionally includes channels 606 (e.g., grooves, scoring, furrows or the like). As shown, the channels 606 extend laterally across at least a portion of the distributor plate 600, for instance, from the plate interior portion 601 to the plate perimeter portion 603. The channels 606 guide and promote flow of the fluid from the central portion 601 to the perimeter portion 603 and, in one example, enhance the consistent distribution of fluid across the compressible reticulated media 402.

FIG. 6B shows another example of a distributor plate 610. In this example, the plate 610 includes another port array 612 having component ports 614, 616, 618, 620 with varying profiles (e.g., sizes, shapes or the like). The port array 612 includes ports 614-620 that generally increase in size from the plate interior portion 601 toward the plate perimeter portion 603. For instance, the ports 618 and 620 proximate the plate perimeter portion 603 are larger than the ports 614 and 616 proximate the plate interior portion 601. In one example, the change in size from the interior 601 toward the exterior promotes distribution of the fluid from the interior across the plate 610 to the larger ports 618, 620 proximate to the perimeter 603. Stated another way, the larger ports 618, 620 more readily delivery fluid to the compressible reticulated media 402 compared to the smaller ports 614, 616. The smaller ports throttle fluid flow and promote lateral delivery of the fluid from the interior portion 601 to the plate perimeter portion 603.

Another distributor plate 630 is shown in FIG. 6C. The plate 630 includes another example port array 634 including a single port extending across at least a portion of the plate 630. For instance, the single port includes a channel 632 (e.g., groove, passage or the like) extending through the distribution plate 630. As shown in FIG. 6C, the channel 632 extends in a serpentine fashion to promote the distribution of the fluid across the plate 630 and delivery across a corresponding distributed portion of the input interface 514 of the compressible reticulated media 402. Although the channel 632 is shown as a serpentine channel in FIG. 6C, the channel 632 includes, but is not limited to, one or more component channels extending laterally across the plate 630, channels extending between ports 636, ports arranged in a linear manner across the plate 630 (e.g., in the manner of linearly arranged perforations).

Optionally, the distributor plate 630 includes one or more ports 636 included as part of the channel 632 and the port array 634. The ports 636 concentrate the delivery of fluid along the channel 632, for instance proximate to the plate perimeter portion 603 where fluid coverage is in some examples minimal relative to the plate center portion 601.

The distributor plates 600, 610, 630 are, in one example, constructed of a robust material including, but not limited to, metal (e.g., aluminum), polymer or the like that is resistant to deflection, for instance otherwise caused by fluids delivered under high pressure to the manifold reservoir 500 (see FIG. 5A). In other examples, the distributor plates 600, 610, 630 are constructed with pliable or elastic materials including, but not limited to, pliable polymers, rubbers, elastomers or the like. Optionally, the distributor plates 600, 620, 630 including pliable or elastic materials include a sealing ridge configured for reception within the gasket recess 506. The distributor plates 600, 620, 630 are coupled with the manifold plate 408, for instance, with one or more fasteners or adhesives to minimize deflection of the pliable or deformable plates.

In other examples, the channels described herein, for instance with the distributor plates 600, 630, are include on the opposed surface of the manifold plate 408 (e.g., along the surface of the plate 408 proximate to the manifold reservoir 500). Channels provided on the manifold plate 408 promote fluid distribution to the ports of the plates 600, 610, 630 in a similar manner to the channels 606, 632 described herein. Optionally, channels on the distribution plates are used in combination with channels provided along the manifold plate 408 to cooperatively promote and direct fluid flow across the distributor plates for delivery to the compressible reticulated media 402.

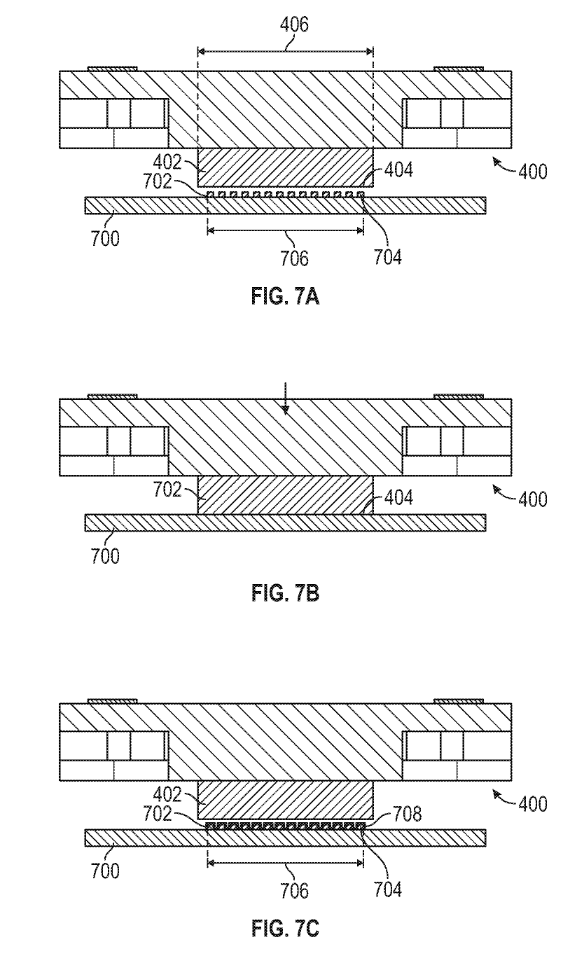

FIGS. 7A-C show the fluid applicator 400 in stages of operation. Beginning with FIG. 7A, the fluid applicator 400 is in a disengaged configuration relative to the substrate 700 and the substrate features 702 including, for instance, the contacts 704. The compressible reticulated media 402 of the fluid applicator 400 is in a saturated configuration. For instance, the reticulations within the compressible reticulated media 402 are filled with one or more fluids including, but not limited to, flux, bonding agents, cleaning fluids or the like. As further shown in FIG. 7A, the applicator profile 406 (also shown in FIGS. 5A, B) of the compressible reticulated media 402 is aligned with and substantially corresponds with a feature profile 706 of the substrate features 702 (in this example, corresponding to the array of contacts 704).

Referring now to FIG. 7B, the fluid applicator 400 is shown in a dispensing configuration depressed toward the substrate 700. As shown, the compressible reticulated media 402 specifically the substrate interface 404 is engaged with the substrate 700. The compressible reticulated media 402 including the reticulations therein is compressed, and the compression of the compressible reticulated media 402 applies fluid from within the reticulations to the substrate 700. For instance, fluid is applied according to the applicator profile 406 of the compressible reticulated media 402 that corresponds with the feature profile 706. The degree of application (e.g., the degree of wetting) of the substrate 700 directly corresponds with the compression of the compressible reticulated media 402. For instance, with additional depression of the fluid applicator 400, additional fluid is supplied from the compressible reticulated media 402 across the feature profile 706. Conversely, minimized engagement and compression of the compressible reticulated media 402 applies less fluid from the reticulations of the compressible reticulated media 402 to the substrate 700.

FIG. 7C shows another view of the fluid applicator 400 after application of the fluid to the substrate 700 along the feature profile 706. In this example, the compressible reticulated media 402 is disengaged from the contacts 704 and the substrate feature 602. The applied fluid 708 is shown as a coating extending along the feature profile 706 and corresponds to the applicator profile 406 shown in previous figures herein. As shown, the applied fluid 708 is localized to the contacts 704 in the feature profile 706 and has not spread, sprayed or migrated away from the feature profile 706, for instance, into other zones in the substrate 700 (e.g., corresponding, for instance, to one or more of the keep out zones previously discussed herein).

As the compressible reticulated media 402 is disengaged from the substrate 700, the media expands (because of its natural elasticity) and accordingly the reticulations are opened. The dilation of the reticulations allows for the flow and filling of the reticulations with fluid, for instance, from one or more of the fluid reservoir, valve assembly or the like shown, for instance, in FIG. 1. In one example, the expansion of the compressible reticulated media 402 passively draws additional fluid into the media. For instance, the expanding reticulations pull fluid into the reticulations from a fluid reservoir, such as the reservoir 106 shown in FIG. 1.

In another example, a valve actuator, electronic control or the like is operated to open the valve, for instance, the valve assembly 108 described and shown in FIG. 1 proximate to the disengagement of the compressible reticulated media 402 from the substrate 700. In one example, the fluid is pressurized and accordingly driven into the expanding reticulations to fill the reticulations and saturate the compressible reticulated media 402. In other examples, the passive filling of the reticulations and pressurized filling of the reticulations are used in combination to fill the reticulations along the substrate interface 404 corresponding to the applicator profile 406. After dispensing of the fluid disengagement of the compressible reticulated media 402 causes refilling of the compressible reticulated media 402 and readies the fluid applicator 400 for the saturated configuration shown in FIG. 7A. That is to say, in one example, the engagement of the compressible reticulated media 402 and application of fluid by way of engagement and depression, in one example, triggers the refilling of the compressible reticulated media 402 and resetting of the fluid applicator 400 to ready it for the next application of fluid.

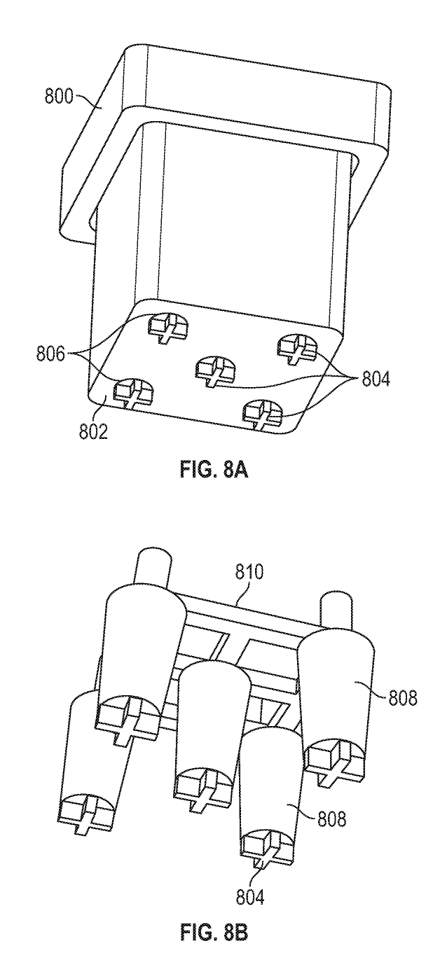

FIGS. 8A and 8B show one example of components of a fluid application system optionally included in the applicator housing 104 shown in FIG. 1. As previously described, the fluid application system 100 includes a fluid reservoir 106 and a valve assembly 108. One example of a fluid reservoir and valve assembly is shown in FIGS. 8A and 8B. Referring first to FIG. 8A, the fluid reservoir 800 is configured to hold one or more fluids such as flux, cleaning agents, bonding agents, epoxies, cleaning solutions or the like. Proximate an end of the fluid reservoir 800, a valve assembly 802 is provided. The valve assembly 802 includes one or more flow orifices 806 extending from the fluid reservoir 800 and through the valve assembly 802 to delivery fluid to a fluid applicator, such as the fluid applicator 102 shown in FIG. 1.

As further shown in FIG. 8A, the valve assembly 802 includes the flow orifices 806 as well as a plug array 804 configured to close and selectively open each of the flow orifices 806. In the example shown in FIG. 8A, the fluid reservoir 800 includes an array of five flow orifices 806. The valve assembly 802 includes a plug array 804 having a corresponding number of plugs to the flow orifices 806.

Referring now to FIG. 8B, the plug array 804 is shown in detail. In this example, the plug array 804 includes five plugs 808 coupled with a plug frame 710. The plug frame 710 is, in one example, coupled with the valve actuator, for instance, a mechanically driven, electrically driven, pneumatically driven operator or the like. As further shown in FIG. 8B, the plugs 808 are optionally formed with a taper. The taper assists, in one example, with reliable seating of the plugs 808 within the flow orifices 806 to prevent the unprompted flow of fluids (leaking) such as flux, cleaning agents or the like through the flow orifices 806.

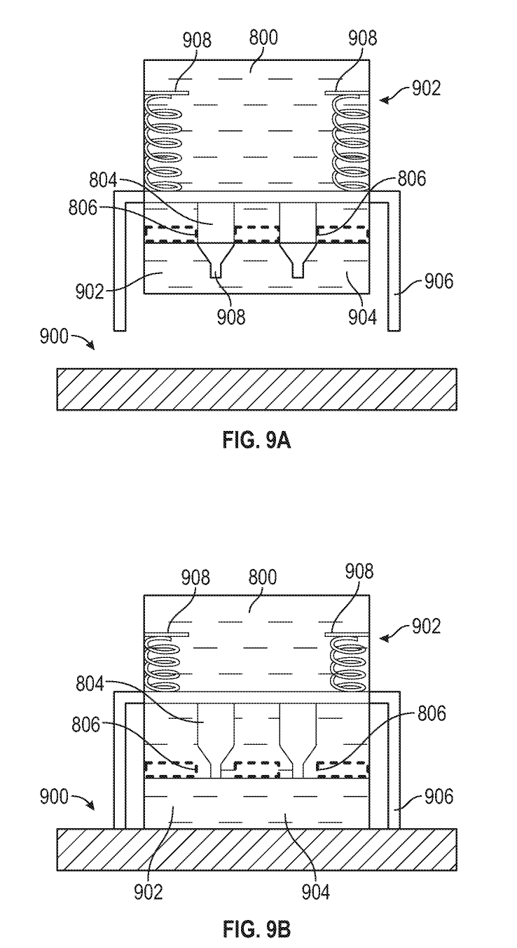

FIGS. 9A and 9B show one example of a fluid applicator 902 including the components previously shown in FIGS. 8A and 8B. FIG. 9A shows the fluid applicator 902 in a saturated configuration prior to engagement with the substrate 900. In contrast, FIG. 9B shows the fluid applicator 902 in a dispensing configuration with the compressible reticulated media 904 engaged with the substrate 900 and partially compressed.

Referring first to FIG. 9A, the fluid applicator 902 is in the saturated configuration. For instance, the compressible reticulated media 904 includes reticulations therein filled with at least one fluid. As shown in FIG. 9A, the plugs 808 of the plug array 804 are seated within the flow orifices 806. In one example, the plug array 804 are biased toward the seated position within the flow orifices 806 by way of an actuator biasing element 908. Optionally, the actuator biasing element 908 includes a spring, elastomer or the like configured to bias the plug array 804 into the closed position shown in FIG. 9A (and similarly shown in FIG. 8A).

As further shown in FIG. 9A, a valve actuator 906 is coupled with the plug array 804. In one example, the valve actuator 906 includes one or more mechanical engagement elements (protrusions, prongs or the like) configured to engage with the substrate 900 and unseat the plug array 804 from the respective flow orifices 806 to facilitate the filling of the compressible reticulated media 904.

Referring now to FIG. 9B, the fluid applicator 902 is shown in a dispensing configuration. In this example, the fluid applicator 902 is depressed toward and engaged with the substrate 900. The compressible reticulated media 904 and its filled reticulations are compressed and the fluid is applied to the substrate 900, for instance, according to an applicator profile of the media as previously described herein. In this example, prior to engagement with the substrate 900, the valve actuator 906 engages the substrate 900 and biases the plug array 804 including the component plugs 808 into an open configuration relative to the flow orifices 806. Accordingly, the fluid reservoir 800 is in communication with the compressible reticulated media 904. As the compressed reticulations expand (e.g., with retraction of the fluid applicator 902 away from the substrate 900) fluid passes from the reservoir 800 and is absorbed in the expanding reticulations.

As the fluid applicator 902 continues to rise relative to the substrate 900, the compressible reticulated media 904 disengages with the substrate 900. Continued elevation of the fluid applicator 902 biases the plug array 804 downwardly (e.g., with the biasing element 908) relative to the compressible reticulated media 904 and the flow orifices 806. The plug array 804 including the component plugs 808 are seated within the flow orifices 806 and close the fluid reservoir 800 to the compressible reticulated media 904.

In one example, the valve actuator 906 is tuned (lengthened, shortened or the like) to open and close the valve assembly 802 at specified points in the travel of the fluid applicator 902. For instance, where wicking of a fluid from the substrate 900 (corresponding to expansion of the reticulations as the compressible reticulated media 904 begins to move away from the substrate 900) is specified the valve actuator 906 includes a shorter actuator. For instance, one or more of the arms extending from the fluid reservoir 800 into engagement with the substrate 900 is shortened relative to the arms (e.g., prongs or protrusions) of the valve actuator 906 shown in FIGS. 9A, B. Accordingly, the flow orifices 806 are closed near to the innitation of elevation of the fluid applicator 902 in an upward direction relative to its initial engagement. The valve assembly 802 is closed prior to complete filling of the reticulations, for instance, from the fluid reservoir 800. Accordingly, the surface energy within the reticulations (e.g., the expansion and corresponding negative pressure created with the expansion) draws at least some of the fluid from the substrate 900 and accordingly prevents pooling, over-application or spreading of the fluid into one or more zones, such as keep out zones (KOZ) or the like.

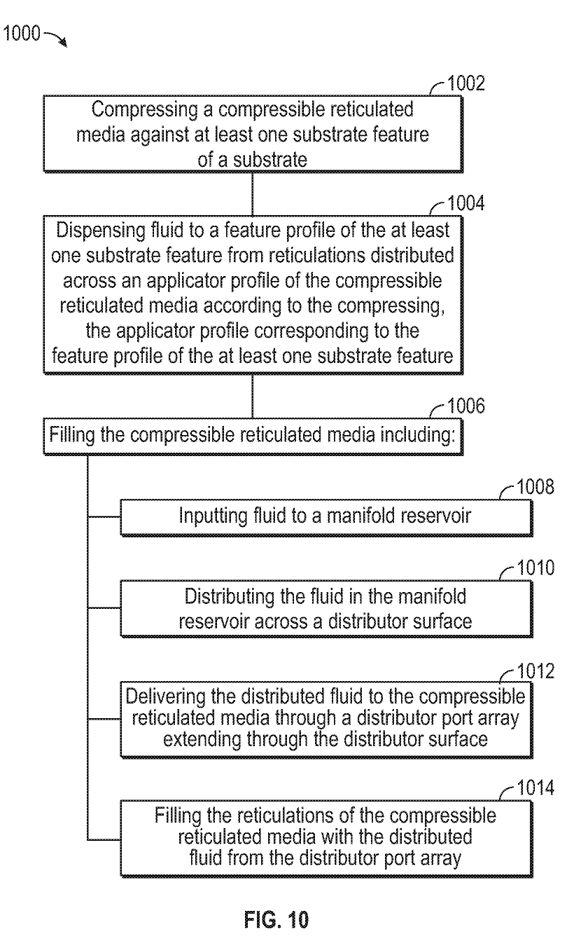

FIG. 10 shows one example of a method 1000 for distributing a fluid in a fluid applicator including one or more of the fluid applicators described herein. In describing the method 1000, reference is made to one or more components, features, functions and steps previously described herein. Where convenient, reference is made to the components, features, steps and the like with reference numerals. The reference numerals provided are exemplary and are not exclusive. For instance, components, features, functions, steps and the like described in the method 1000 include, but are not limited to, the corresponding numbered elements provided herein and other corresponding elements described herein (both numbered and unnumbered) as well as their equivalents.

At 1002, a compressible reticulated media 402 is compressed against at least one substrate feature 702 of a substrate 700 (see FIGS. 7A-C). For instance, the media 402 is depressed toward and engaged with the substrate 700. As described herein, the media 402 is aligned with one or more substrate features 702.

At 1004, the method 1000 includes dispensing fluid to a feature profile 706 of the at least one substrate feature 702 from reticulations distributed across an applicator profile 406 of the compressible reticulated media 402 according to the compressing. The applicator profile 406 corresponds to the feature profile 706 of the at least one substrate feature 702. Accordingly, compression of the compressible reticulated media 402 applies a film, layer or coating of the fluid to the substrate feature 702. The fluid is applied consistently and accurately to the substrate feature 702 according to the applicator profile 406 corresponding to the feature profile 706.

At 1006, the compressible reticulated media 402 is filled, for instance, for another application of the fluid to the substrate 700 or another substrate 700 moved into alignment with the media 402 of the applicator. Filling of the media 402 includes at 1008 inputting fluid to a manifold reservoir, such as the reservoir 500 shown in FIG. 5A. As shown in FIG. 5A, in one example the fluid is received in the reservoir 500 from an inflow orifice 502. A valve assembly 108 optionally controls the flow of fluid to the reservoir 500 with one or more mechanical or electronic control. Filling further includes at 1010, distributing the fluid in the manifold reservoir 500 across a distributor surface, such as the distributor plate 600 (610 or 630). As described herein, the distributor plate is optionally structurally robust (e.g., rigid) or pliable (e.g., like a rubber). At 1012, the distributed fluid is delivered to the compressible reticulated media 402 through a distributor port array 602 (612 or 634) extending through the distributor surface (e.g., the respective plates). As described herein, the distributor port array includes one or more ports (e.g., holes, orifices, perforations, grooves, channels or the like). The distributor port array is optionally coincident with the applicator profile 406. For instance, at least a portion of the applicator profile 406 lies beneath the distributor port array. At 1014, the reticulations of the compressible reticulated media 402 are filled with the distributed fluid from the distributor port array. In one example, the expansion of the compressible reticulated media 402 after compression in a preceding application of the fluid opens (e.g., dilates) the reticulations and facilitates the drawing of fluid into the reticulations.

Several options for the method 1000 follow. In one example, filling the compressible reticulated media 402 includes expanding the compressible reticulated media after compressing. In another example, filling the reticulations of the compressible reticulated media 402 includes filling the reticulations according to a reticulation diameter of the reticulations and the degree of compression and elasticity of the compressible reticulated media. In a further option, filling the reticulations of the compressible media 402 includes filling the reticulations distributed from an interior 510 the applicator profile 406 to a perimeter 512 of the applicator profile 406 after each compressing of the media and dispensing of fluid.

In another example, the method 1000 includes continuously retaining the compressible reticulated media along the distributor surface (e.g., a distributor plate) during each of compressing, dispensing and filling. For instance, the compressible reticulated media 402 is coupled along the distributor plate to prevent deformation, including sagging, of the media 402 with repeated applications of the fluid. In one example, the media 402 is adhered to the distributor plate. In another example, the media 402 is fastened to the distributor plate, for instance, with rivets, screws, deformable barbs or the like.

### Various Notes & Examples

Example 1 can include subject matter such as a fluid applicator configured to apply a fluid to at least one substrate feature of a substrate, the fluid applicator comprising: a manifold plate having an inflow orifice and a manifold reservoir; a distributor plate coupled with the manifold plate, the distributor plate includes: a distributor surface extending across the manifold reservoir, and a distributor port array spread across the distributor surface and in communication with the manifold reservoir; and a compressible reticulated media configured for applying the fluid to the at least one substrate feature, the compressible reticulated media includes: an input interface coupled along the distributor surface, a substrate interface having an applicator profile corresponding to a feature profile of the at least one substrate feature, and reticulations extending from the input interface to the substrate interface, the reticulations distributed across the substrate interface.

Example 2 can include, or can optionally be combined with the subject matter of Example 1, to optionally include wherein the compressible reticulated media is fastened along the distributor surface.

Example 3 can include, or can optionally be combined with the subject matter of one or any combination of Examples 1 or 2 to optionally include wherein the compressible reticulated media is adhered along the distributor surface.

Example 4 can include, or can optionally be combined with the subject matter of one or any combination of Examples 1-3 to optionally include wherein the substrate interface includes an applicator profile corresponding to a feature profile of the at least one substrate feature.

Example 5 can include, or can optionally be combined with the subject matter of one or any combination of Examples 1-4 to optionally include wherein the reticulations are continuously distributed from an interior of the applicator profile to a perimeter of the applicator profile.

Example 6 can include, or can optionally be combined with the subject matter of Examples 1-5 to optionally include wherein the distributor port array includes a plurality of ports spread across the distributor surface.

Example 7 can include, or can optionally be combined with the subject matter of Examples 1-6 to optionally include wherein the distributor surface extends laterally away from the inflow orifice of the manifold plate, and the distributor port array is spread laterally from the inflow orifice.

Example 8 can include, or can optionally be combined with the subject matter of Examples 1-7 to optionally include wherein the distributor surface is aligned with the inflow orifice and interposed between the inflow orifice and the compressible reticulated media.

Example 9 can include, or can optionally be combined with the subject matter of Examples 1-8 to optionally include a retention frame coupled with the manifold plate, and the compressible reticulated media is clamped between the manifold plate and the retention frame.

Example 10 can include, or can optionally be combined with the subject matter of Examples 1-9 to optionally include wherein the distributor plate is clamped between the manifold plate and the retention frame.

Example 11 can include, or can optionally be combined with the subject matter of Examples 1-10 to optionally include one or more decoupling elements coupled with the manifold plate and extending beyond the substrate interface.

Example 12 can include, or can optionally be combined with the subject matter of Examples 1-11 to optionally include wherein the one or more decoupling elements include a pin and a biasing element.

Example 13 can include, or can optionally be combined with the subject matter of Examples 1-12 to optionally include a fluid application system configured to apply a fluid to at least one substrate feature of a substrate, the fluid application system comprising: an applicator housing including a fluid reservoir; a fluid applicator coupled with the applicator housing, the fluid applicator includes: a manifold plate having an inflow orifice; a distributor plate coupled with the manifold plate, the distributor plate includes: a distributor surface extending laterally from the inflow orifice, and a distributor port array spread across the distributor surface and in communication with the inflow orifice; and a compressible reticulated media configured for applying the fluid to the at least one substrate feature, the compressible reticulated media includes: an input interface coupled along the distributor surface, a substrate interface having an applicator profile corresponding to a feature profile of the at least one substrate feature, and reticulations extending from proximate the distributor port array to the substrate interface; and a valve assembly between the fluid reservoir and the compressible reticulated media, wherein the valve assembly includes a valve actuator configured to open and close the fluid reservoir during one or more of filling or dispensing of the fluid from the compressible reticulated media.

Example 14 can include, or can optionally be combined with the subject matter of Examples 1-13 to optionally include wherein the reticulations are distributed across the applicator profile.

Example 15 can include, or can optionally be combined with the subject matter of Examples 1-14 to optionally include wherein the reticulations are continuously distributed from an interior of the applicator profile to a perimeter of the applicator profile.

Example 16 can include, or can optionally be combined with the subject matter of Examples 1-15 to optionally include wherein the applicator profile corresponds with a feature profile of the at least one substrate feature, and comprising a substrate fixture configured for holding the substrate and maintaining alignment between the feature profile of the at least one substrate feature and the applicator profile of the substrate interface.

Example 17 can include, or can optionally be combined with the subject matter of Examples 1-16 to optionally include wherein the valve assembly includes a valve actuator configured to open the fluid reservoir in a filling configuration with the compressible reticulated media disengaged from the substrate feature.

Example 18 can include, or can optionally be combined with the subject matter of Examples 1-17 to optionally include a retention frame coupled with the manifold plate, and the compressible reticulated media and the distributor plate are clamped between the manifold plate and the retention frame.

Example 19 can include, or can optionally be combined with the subject matter of Examples 1-18 to optionally include one or more decoupling elements coupled with the manifold plate and extending beyond the substrate interface.

Example 20 can include, or can optionally be combined with the subject matter of Examples 1-19 to optionally include wherein the one or more decoupling elements are configured to bias the substrate away from the compressible reticulated media with movement of the compressible reticulated media away from the substrate.

Example 21 can include, or can optionally be combined with the subject matter of Examples 1-20 to optionally include the substrate having the at least one substrate feature.

Example 22 can include, or can optionally be combined with the subject matter of Examples 1-21 to optionally include a method for distributing fluid in a fluid applicator comprising: compressing a compressible reticulated media against at least one substrate feature of a substrate; dispensing fluid to a feature profile of the at least one substrate feature from reticulations distributed across an applicator profile of the compressible reticulated media according to the compressing, the applicator profile corresponding to the feature profile of the at least one substrate feature; and filling the compressible reticulated media including: inputting fluid to a manifold reservoir, distributing the fluid in the manifold reservoir across a distributor surface, delivering the distributed fluid to the compressible reticulated media through a distributor port array extending through the distributor surface, and filling the reticulations of the compressible reticulated media with the distributed fluid from the distributor port array.

Example 23 can include, or can optionally be combined with the subject matter of Examples 1-22 to optionally include wherein filling the compressible reticulated media includes expanding the compressible reticulated media after compressing.

Example 24 can include, or can optionally be combined with the subject matter of Examples 1-23 to optionally include wherein filling the reticulations of the compressible reticulated media includes filling the reticulations according to a reticulation diameter of the reticulations and the degree of compression and elasticity of the compressible reticulated media.

Example 25 can include, or can optionally be combined with the subject matter of Examples 1-24 to optionally include wherein filling the reticulations of the compressible media includes filling the reticulations distributed from an interior of the applicator profile to a perimeter of the applicator profile after each compressing and dispensing.

Each of these non-limiting examples can stand on its own, or can be combined in various permutations or combinations with one or more of the other examples.

The above detailed description includes references to the accompanying drawings, which form a part of the detailed description. The drawings show, by way of illustration, specific embodiments in which the disclosure can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the disclosure should be determined with reference to the appended claims, along with the full scope of equivalents to which such claims are entitled.

What is claimed is:

1. A fluid applicator configured to apply a fluid to at least one substrate feature of a substrate, the fluid applicator comprising:
a manifold plate having an inflow orifice and a manifold reservoir;
a distributor plate coupled with the manifold plate, the distributor plate includes:
a distributor surface extending across the manifold reservoir, and
a distributor port array spread across the distributor surface and in communication with the manifold reservoir; and
a compressible reticulated media configured for applying the fluid to the at least one substrate feature, the compressible reticulated media includes:
an input interface coupled along the distributor surface,
a substrate interface having an applicator profile corresponding to a feature profile of the at least one substrate feature, and
reticulations extending from the input interface to the substrate interface, the reticulations distributed across the substrate interface.

2. The fluid applicator of claim 1, wherein the compressible reticulated media is fastened along the distributor surface.

3. The fluid applicator of claim 1, wherein the compressible reticulated media is adhered along the distributor surface.

4. The fluid applicator of claim 1, wherein the substrate interface includes an applicator profile corresponding to a feature profile of the at least one substrate feature.

5. The fluid applicator of claim 4, wherein the reticulations are continuously distributed from an interior of the applicator profile to a perimeter of the applicator profile.

6. The fluid applicator of claim 1, wherein the distributor port array includes a plurality of ports spread across the distributor surface.

7. The fluid applicator of claim 1, wherein the distributor surface extends laterally away from the inflow orifice of the manifold plate, and the distributor port array is spread laterally from the inflow orifice.

8. The fluid applicator of claim 1, wherein the distributor surface is aligned with the inflow orifice and interposed between the inflow orifice and the compressible reticulated media.

9. The fluid applicator of claim 1 comprising a retention frame coupled with the manifold plate, and the compressible reticulated media is clamped between the manifold plate and the retention frame.

10. The fluid applicator of claim 9, wherein the distributor plate is clamped between the manifold plate and the retention frame.

11. The fluid applicator of claim 1 comprising one or more decoupling elements coupled with the manifold plate and extending beyond the substrate interface.

12. The fluid applicator of claim 11, wherein the one or more decoupling elements include a pin and a biasing element.

13. A fluid application system configured to apply a fluid to at least one substrate feature of a substrate, the fluid application system comprising:
an applicator housing including a fluid reservoir;
a fluid applicator coupled with the applicator housing, the fluid applicator includes:
a manifold plate having an inflow orifice;
a distributor plate coupled with the manifold plate, the distributor plate includes:
a distributor surface extending laterally from the inflow orifice, and
a distributor port array spread across the distributor surface and in communication with the inflow orifice; and
a compressible reticulated media configured for applying the fluid to the at least one substrate feature, the compressible reticulated media includes:
an input interface coupled along the distributor surface,
a substrate interface having an applicator profile corresponding to a feature profile of the at least one substrate feature, and
reticulations extending from proximate the distributor port array to the substrate interface; and
a valve assembly between the fluid reservoir and the compressible reticulated media, wherein the valve assembly includes a valve actuator configured to open and close the fluid reservoir during one or more of filling or dispensing of the fluid from the compressible reticulated media.

14. The fluid application system of claim 13, wherein the reticulations are distributed across the applicator profile.

15. The fluid application system of claim 13, wherein the reticulations are continuously distributed from an interior of the applicator profile to a perimeter of the applicator profile.

16. The fluid application system of claim 13, wherein the applicator profile corresponds with a feature profile of the at least one substrate feature, and
comprising a substrate fixture configured for holding the substrate and maintaining alignment between the feature profile of the at least one substrate feature and the applicator profile of the substrate interface.

17. The fluid application system of claim 13, wherein the valve assembly includes a valve actuator configured to open the fluid reservoir in a filling configuration with the compressible reticulated media disengaged from the substrate feature.

18. The fluid application system of claim 13 comprising a retention frame coupled with the manifold plate, and the compressible reticulated media and the distributor plate are clamped between the manifold plate and the retention frame.

19. The fluid application system of claim 13 comprising one or more decoupling elements coupled with the manifold plate and extending beyond the substrate interface.

20. The fluid applicator of claim 19, wherein the one or more decoupling elements are configured to bias the substrate away from the compressible reticulated media with movement of the compressible reticulated media away from the substrate.

21. The fluid application system of claim 13 comprising the substrate having the at least one substrate feature.

22. A method for distributing fluid in a fluid applicator comprising:
compressing a compressible reticulated media against at least one substrate feature of a substrate;
dispensing fluid to a feature profile of the at least one substrate feature from reticulations distributed across an applicator profile of the compressible reticulated media according to the compressing, the applicator profile corresponding to the feature profile of the at least one substrate feature; and
filling the compressible reticulated media including:
inputting fluid to a manifold reservoir,
distributing the fluid in the manifold reservoir across a distributor surface,
delivering the distributed fluid to the compressible reticulated media through a distributor port array extending through the distributor surface, and
filling the reticulations of the compressible reticulated media with the distributed fluid from the distributor port array.

23. The method of claim 22, wherein filling the compressible reticulated media includes expanding the compressible reticulated media after compressing.

24. The method of claim 22, wherein filling the reticulations of the compressible reticulated media includes filling the reticulations according to a reticulation diameter of the reticulations and the degree of compression and elasticity of the compressible reticulated media.

25. The method of claim 22, wherein filling the reticulations of the compressible media includes filling the reticulations distributed from an interior of the applicator profile to a perimeter of the applicator profile after each compressing and dispensing.
